(19) United States
(12) Patent Application Publication
(10) Pub. No.: US 2005/0019992 A1
(43) Pub. Date: Jan. 27, 2005

(54) Method for manufacturing gate electrode for use in semiconductor device

(76) Inventors: Byung-Seop Hong, Ichon-shi (KR); Jae-Geun Oh, Ichon-shi (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/739,653

(22) Filed: Dec. 17, 2003

(30) Foreign Application Priority Data
Jul. 26, 2003 (KR) 2003-51743

(51) Int. Cl. H01L 21/00; H01L 21/84; H01L 21/336

(52) U.S. Cl. 438/149

(57) ABSTRACT

A method for manufacturing an enhanced tungsten gate electrode for use in a semiconductor device is disclosed to adopt a selective oxidation process in an inert gas or a nitrogen gas ambient. The method includes the steps of: preparing a semiconductor substrate obtained by a predetermined process; forming a gate oxide layer on the semiconductor substrate; forming a tungsten polymetal gate electrode including a polysilicon and a tungsten formed on the gate oxide layer in sequence; and carrying out a selective oxidation process in an ambient of a source gas containing hydrogen gas (H₂) diluted with an inert gas or a nitrogen gas for forming a selective oxide on sidewalls of the polysilicon.

### FIELD OF THE INVENTION

The present invention relates to a method for manufacturing a semiconductor device; and, more particularly, to a method for manufacturing a tungsten polymetal gate electrode for use in a semiconductor device by employing an enhanced selective oxidation process to prevent the semiconductor device from being contaminated due to a tungsten vapor.

### DESCRIPTION OF THE PRIOR ART

Typically, since a process for manufacturing a polysilicon gate electrode is relatively stable, a doped polysilicon has been popularly used for a gate electrode in manufacturing a metal oxide semiconductor (MOS) transistor. With highly integrated semiconductor device, however, all the patterns in the device become more and more micronized so that a linewidth in the device becomes less than 100 nm or 80 nm.

Accordingly, it is difficult to apply the conventional polysilicon electrode to a modern semiconductor device requiring a high speed and a rapid refresh time because the doped polysilicon has a high specific resistance and a long delay time. To overcome the above problem, a new technique for forming the gate electrode has been developed such as a polycide gate electrode which includes polysilicon and silicide therein.

However, the polycide gate electrode has still a limitation to be applicable for a new generation highly integrated device. Therefore, in recent years, many researches have been progressed to employ a refractory metal for the gate electrode. Furthermore, in order to secure a low specific resistance, there is proposed a polymetal gate electrode in which the refractory metal such as tungsten (W) and the polysilicon are stacked on an underlying gate oxide layer in sequence.

Hereinafter, a conventional polymetal gate electrode, especially tungsten gate electrode, will be illustrated.

In manufacturing the conventional tungsten polymetal gate electrode, a dry etching process should be carried out for patterning a tungsten layer and an underlying polysilicon layer into a desired shape. During the dry etching process, however, edges of the gate structure and a semiconductor substrate are inevitably damaged due to plasma. Therefore, in order to recover the damage incurred during the dry etch process, a re-oxidation process should be performed in general. Preferably, a selective oxidation process is carried out in oxidation ambient at a high temperature for selectively oxidizing the polysilicon layer and the semiconductor substrate without oxidizing the tungsten layer. Another reasons of carrying out the selective oxidation process is to prevent a decrease of a data retention time and to enhance a refresh property, whereby it is possible to secure a good gate induced drain leakage (GIDL) property in a DRAM device having the gate structure of tungsten/barrier/polysilicon therein by means of the selective oxidation process.

The conventional selective oxidation process, in detail, is carried out in wet vapor (H₂O) and hydrogen rich ambient so that a tungsten vapor (WH₂O₄) is inevitably produced by an inter-reaction between the tungsten layer and H₂O. As a result, a selective oxidation equipment and a surface of a semiconductor wafer becomes contaminated due to the tungsten vapor.

Such contamination due to the tungsten vapor generates defects such as a trap site or a tungsten silicide (WSix) in a cell junction area or a gate channel so that results in an increase of leakage current and a deteriorated refresh property of the DRAM device. Furthermore, while forming a gate sealing nitride for protecting the gate structure during post manufacturing process, a supplementary contamination of tungsten vapor is happened due to a thermal budget experienced before forming the gate sealing nitride. In addition, since the gate sealing nitride is formed on the gate structure instantly, contaminated tungsten substances remain still on the wafer, thereby incurring deterioration of the gate channel or the cell junction area during a post thermal process.

### SUMMARY OF THE INVENTION

It is, therefore, an object of the present invention to provide a method for manufacturing a tungsten polymetal gate electrode for use in a semiconductor device with an enhanced property by carrying out a selective oxidation process in an inert gas ambient or a nitrogen gas ambient.

In accordance with one aspect of the present invention, there is provided a method for manufacturing a gate electrode for use in a semiconductor device, the method including the steps of: a) preparing a semiconductor substrate obtained by a predetermined process; b) forming a gate oxide layer, a on the semiconductor substrate; c) forming a tungsten polymetal gate electrode including a polysilicon and a tungsten formed on the gate oxide layer in sequence; and d) carrying out a selective oxidation process in an ambient of a source gas containing hydrogen gas (H₂) diluted with an inert gas for forming a selective oxide on sidewalls of the polysilicon.

In accordance with another aspect of the present invention, there is provided a method for manufacturing a gate electrode for use in a semiconductor device, the method including the steps of: a) preparing a semiconductor substrate obtained by a predetermined process; b) forming a gate oxide layer on the semiconductor substrate; c) forming a tungsten polymetal gate electrode including a polysilicon and a tungsten formed on the gate oxide layer in sequence; and d) carrying out a selective oxidation process in an ambient of a source gas containing hydrogen gas diluted with a nitrogen gas for forming a selective oxide on sidewalls of the polysilicon.

### BRIEF DESCRIPTION OF THE DRAWINGS

The above and other objects and features of the present invention will become apparent from the following description of the preferred embodiments given in conjunction with the accompanying drawings, in which:

FIGS. 1A to 1D are cross sectional views setting forth a method for manufacturing a tungsten polymetal gate electrode for use in a semiconductor device in accordance with a preferred embodiment of the present invention

### DETAILED DESCRIPTION OF THE PREFERRED EMBODIMENTS

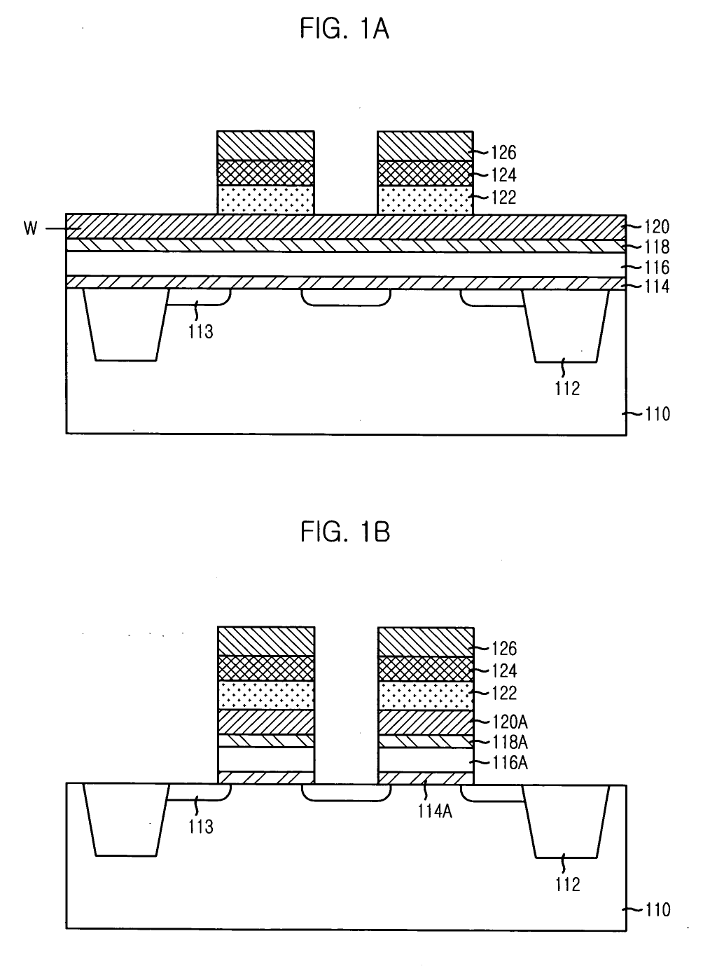

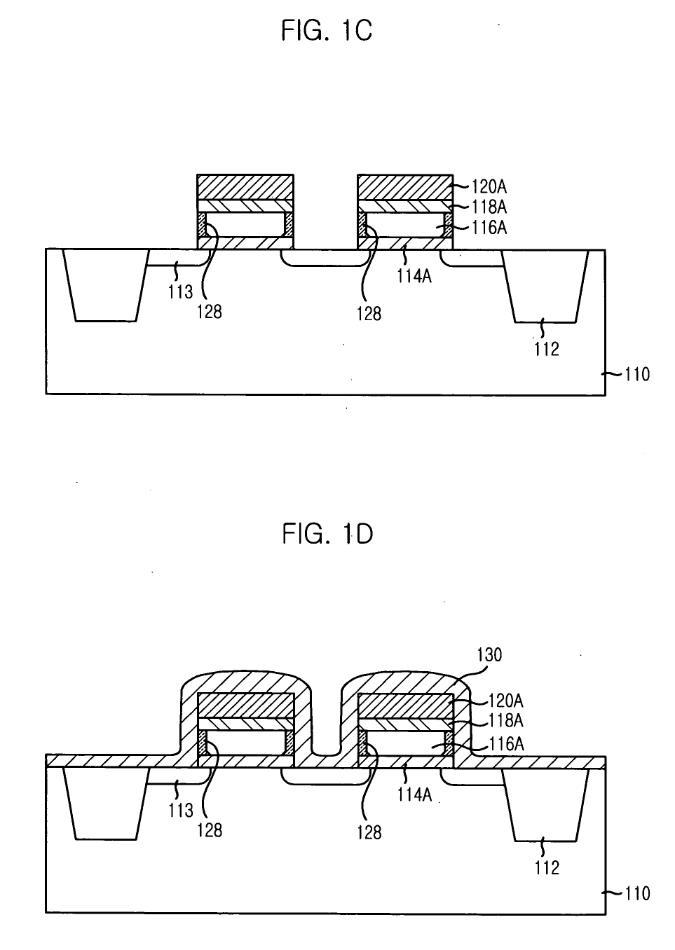

There are provided in FIGS. 1A to 1D cross sectional views setting forth a method for manufacturing a tungsten polymetal gate electrode for use in a semiconductor device in accordance with a preferred embodiment of the present invention.

Referring to FIG. 1A, the inventive method for manufacturing the tungsten polymetal gate electrode begins with preparation of a semiconductor substrate 110 obtained by a predetermined process. Isolation regions 112 and source/drain regions 113 are formed in predetermined locations of the semiconductor substrate 110 by using a typical method. Thereafter, a gate oxide layer 114 and a polysilicon layer 116 are formed on the semiconductor substrate 110 sequentially.

Subsequently, a barrier layer 118 is formed on the polysilicon layer 116 for preventing an inter-diffusion between the polysilicon layer 116 and a tungsten layer 120, wherein the barrier layer 118 uses a material such as a tungsten nitride, a titanium nitride, a tungsten silicide, a silicon nitride or the like. Following the formation of the barrier layer 118, the tungsten layer 120 of a refractory metal is formed on the barrier layer 118. Afterward, a hard mask 122 is formed on predetermined locations of the tungsten layer 120 by using a material such as a plasma enhanced silicon nitride or a low pressure silicon nitride.

Thereafter, an anti-reflection coating (ARC) layer is formed on the hard mask layer by using a material such as silicon oxi-nitride (SiON). It is known that using the ARC layer can minimize reflective notching and critical dimension variations caused by reflection of light during a photolithographic process. Then, a photoresist layer is formed on a top face of the ARC layer and is patterned by means of a light exposure and a development process so as to form a photoresist mask 126 on the ARC layer.

After forming the photoresist mask 126, the ARC layer and the hard mask layer are patterned into a first predetermined configuration by making use of the photoresist mask 126 as a mask, thereby obtaining an ARC mask 124 and a hard mask 122. Afterward, the photoresist mask 126 is removed by using a method such as a photoresist strip process and then, a cleaning process may be carried out for clearing off residues.

In a next step, referring to FIG. 1B, the tungsten layer 120, the barrier layer 118, the polysilicon layer 116 and the gate oxide layer 114 are sequentially patterned into a second predetermined configuration by means of a plasma process using the ARC mask 124 and the hard mask 122, thereby forming a gate structure having a tungsten 120A, a diffusion barrier 118A, a polysilicon 116A and a gate oxide 114A. During the plasma process, the semiconductor substrate 110 and gate oxide 114A are unavoidably attacked. Therefore, in order to recover damage and to secure a gate induced drain leakage (GIDL) property, a selective oxidation process should be carried out.

In the present invention, the selective oxidation process is carried out in an ambient of a mixed gas diluted with an inert gas or a nitrogen gas having a predetermined ratio, thereby restraining tungsten vapor (WH₂O₄) which is produced during the selective oxidation process in the prior art method. Moreover, the selective oxidation process of the present invention can effectively purge out tungsten vapor before tungsten vapor is introduced into the semiconductor substrate or a selective oxidation equipment, whereby a tungsten contamination is prevented effectively.

The selective oxidation process of the present invention will be more illustrated in detail hereinafter.

The inventive selective oxidation process is carried out in an equipment such as a rapid thermal process (RTP) chamber in the ambient of mixed gas of H₂O and H₂ diluted with the inert gas or the nitrogen gas. Herein, conditions for carrying out the selective oxidation process as followings: a mixing ratio of H₂O to H₂ is in a range of about 0.01 to 1 to about 1 to 1; an oxidation process temperature is in a range of about 800° C. to about 1,000° C.; a process time for oxidation ranges about 1 second to about 600 second; and selective oxides 128 formed after the selective oxidation process have the thickness in the range of about 1 Å to about 100 Å.

Herein, it is preferable that the inert gas such as argon (Ar), neon (Ne), helium (He) or the like should be supplied into the chamber with amount in the range of about 0.001 slpm to about 50 slpm. Alternatively, it is preferable that the nitrogen gas should be supplied into the chamber in a ratio of about 0.001 slpm to about 50 slpm. By carrying out the selective oxidation process, the tungsten vapor is easily removed by means of a heavy molecular weight gas, i.e., inert gas or nitrogen gas, so that the contamination incurred by the tungsten vapor can be prevented.

Referring to table 1, there is shown an experimental data resulted after carrying out the selective oxidation process in comparison with the prior art method and the inventive method.

TABLE 1

| SAMPLE | D (prior art) | E (present invention) |
|---|---|---|
| Temperature (° C.) | 930 | 930 |
| Time (second) | 120 | 120 |
| O₂ Flow rate (slpm) | 0.47 | 0.47 |
| L-H₂ Flow rate (slpm) | 5.00 | 5.00 |
| H₂ Flow rate (slpm) | 10.00 | 2.50 |
| N₂ Flow rate (slpm) | 0.00 | 7.50 |
| Steam (%) | 6.27 | 6.27 |
| H₂O:H₂ (%) | 6.7 | 14.3 |
| Oxide thickness (Å) | 32.44 | 33.40 |
| 1 sigma (%) | 2.17 | 1.02 |
| W contamination | 93 | 34 |
| (atom/cm²) | | |

Herein, the sample D was subjected to the prior art selective oxidation process and the sample E was subjected to the inventive selective oxidation process. The denotation of 1 sigma means a standard deviation of the oxide thickness and the denotation of the W contamination means how many W atoms are distributed in a unit area owing to tungsten vapor produced during the selective oxidation process.

In table 1, while the W contamination of the sample D shows 93 atom/cm² according to the prior art method, that of the sample E represents 34 atom/cm². That is, the W contamination of the sample E decreases with respect to that of the sample D by employing nitrogen gas in the present invention. Moreover, the standard deviation of the oxide thickness of the sample E is smaller than that of the sample D so that the oxide thickness of the sample E becomes more uniform than the sample D, wherein the selective oxides 128 are formed on sidewalls of the polysilicon 116A. As the oxide thickness is uniform, key parameters such as a threshold voltage or the like is also enhanced, thereby obtaining a device with a high reliability and increasing a yield of products.

Referring to FIG. 1C, there is shown a cross sectional view of the gate electrode after performing the selective oxidation process, wherein the selective oxides 128 having bird's beak are formed on the side walls of the polysilicon 116A and edges of the polysilicon 116A.

After the selective oxidation process, a cleaning process is carried out by using a fluoric acid (HF) or a buffered oxide etchant (BOE) for removing residual impurities containing WH₂O₄. Alternatively, a mixed solution containing a sulfuric acid (H₂SO₄) can be used for removing residual impurities, wherein the mixed solution containing sulfuric acid is prepared by diluting sulfuric acid with water having a mixing ratio of water ranging from about 2 to about 10 with respect to a fixed sulfuric acid having a mixing ratio of 1 or a mixing ratio of sulfuric acid ranging from about 30 to about 100 with respect to a fixed hydrogen peroxide (H₂O₂) having a mixing ratio of 1. Furthermore, the cleaning process can be carried by using a mixed solution of the sulfuric acid and the fluoric acid with a predetermined mixing ratio.

Following the cleaning process, referring to FIG. 1D, a gate sealing nitride 130 is formed over the resultant structure including the gate electrode and the semiconductor substrate 110 with the thickness ranging from about 30 Å to about 500 Å for protecting the gate electrode during post processes, by using a method such as a low pressure chemical vapor deposition (LPCVD) or the like.

In comparison with the prior art method, the selective oxidation process of the present invention is carried out in the inert gas ambient or in the nitrogen gas ambient, whereby the tungsten contamination due to the tungsten vapor is effectively prevented. Furthermore, since the selective oxides 128 formed on the sidewalls of the polysilicon 116A has uniform thickness, the present invention provides an advantage that a cell transistor has an enhanced electrical property and reliability.

While the present invention has been described with respect to the particular embodiments, it will be apparent to those skilled in the art that various changes and modifications may be made without departing from the scope of the invention as defined in the following claims.

1. A method for manufacturing a gate electrode of a semiconductor device, the method comprising the steps of:
a) preparing a semiconductor substrate obtained by a predetermined process;
b) forming a gate oxide layer on the semiconductor substrate;
c) forming a tungsten polymetal gate electrode including a polysilicon and a tungsten formed on the gate oxide layer in sequence; and
d) carrying out a selective oxidation process in an ambient of a source gas containing hydrogen gas (H₂) diluted with an inert gas for forming a selective oxide on sidewalls of the polysilicon.

2. The method as recited in claim 1, wherein the step d) is carried out in a rapid thermal process (RTP) chamber at a temperature ranging from about 800° C. to about 1,000° C. by using the source gas containing vapor (H₂O) and hydrogen (H₂) in which a mixing ratio of H₂O to H₂ is in a range of about 0.01:1 to about 1:1.

3. The method as recited in claim 1, wherein the inert gas is supplied into the chamber with amount in a range of about 0.001 slpm to about 50 slpm.

4. The method as recited in claim 3, wherein the inert gas uses a material selected from the group consisting of argon (Ar), neon (Ne) and helium (He).

5. The method as recited in claim 1, after the step d), further comprising the steps of:
e) carrying out a cleaning process by using a solution; and
f) forming a gate sealing nitride embracing the tungsten polymetal gate electrode and the semiconductor substrate.

6. The method as recited in claim 5, wherein the solution is a mixed solution containing sulfuric acid (H₂SO₄) diluted with water, a mixing ratio of water ranging from about 2 to about 10 with respect to a fixed sulfuric acid having a mixing ratio of 1.

7. The method as recited in claim 5, wherein the solution is a mixed solution of sulfuric acid and hydrogen peroxide (H₂O₂), a mixing ratio of H₂SO₄ ranging from about 30 to about 100 with respect to a fixed hydrogen peroxide having a mixing ratio of 1.

8. The method as recited in claim 5, wherein the solution uses fluoric acid (HF).

9. The method as recited in claim 5, wherein the solution uses buffered oxide etchant (BOE).

10. The method as recited in claim 5, wherein the gate sealing nitride is formed with a thickness ranging from about 30 Å to about 500 Å by using a low pressure chemical vapor deposition (LPCVD) technique.

11. The method as recited in claim 1, wherein the step c) includes the steps of:
c1) forming a polysilicon layer, a barrier layer, a tungsten layer, a hard mask layer and an anti-reflection coating (ARC) layer on the gate oxide layer in sequence;
c2) patterning the ARC layer and the hard mask layer by using a photoresist mask formed on the ARC layer, thereby forming an ARC layer and a hard mask; and
c3) forming the tungsten polymetal gate electrode by patterning the tungsten layer, the barrier layer, the polysilicon layer and the gate oxide layer into a predetermined configuration using the ARC mask and the hard mask.

12. The method as recited in claim 1, wherein the selective oxide has the thickness in the range of about 1 Å to about 100 Å.

13. A method for manufacturing a gate electrode of a semiconductor device, the method comprising the steps of:
a) preparing a semiconductor substrate obtained by a predetermined process;
b) forming a gate oxide layer on the semiconductor substrate;
c) forming a tungsten polymetal gate electrode including a polysilicon and a tungsten formed on the gate oxide layer in sequence; and
d) carrying out a selective oxidation process in an ambient of a source gas containing hydrogen gas diluted with a nitrogen gas for forming a selective oxide on sidewalls of the polysilicon.

14. The method as recited in claim 13, wherein the step d) is carried out in an RTP chamber at a temperature ranging from about 800° C. to about 1,000° C. by using the source gas containing vapor (H₂O) and H₂ in which a mixing ratio of H₂O to H₂ is in the range of about 0.01:1 to about 1:1.

15. The method as recited in claim 13, wherein the nitrogen gas is supplied into the chamber with amount in the range of about 0.001 slpm to about 50 slpm.

16. The method as recited in claim 13, after the step d), further comprising the steps of:
e) carrying out a cleaning process by using a solution; and
f) forming a gate sealing nitride embracing the tungsten polymetal gate electrode and the semiconductor substrate.

17. The method as recited in claim 16, wherein the solution is a mixed solution containing sulfuric acid diluted with water, a mixing ratio of water ranging from about 2 to about 10 with respect to a fixed sulfuric acid having a mixing ratio of 1.

18. The method as recited in claim 16, wherein the solution is a mixed solution of sulfuric acid and hydrogen peroxide, a mixing ratio of sulfuric acid ranging from about 30 to about 100 with respect to a fixed hydrogen peroxide having a mixing ratio of 1.

19. The method as recited in claim 16, wherein the solution uses fluoric acid (HF).

20. The method as recited in claim 16, wherein the solution uses buffered oxide etchant (BOE).

21. The method as recited in claim 16, wherein the gate sealing nitride is formed with a thickness ranging from about 30 Å to about 500 Å by using a low pressure chemical vapor deposition (LPCVD) technique.

22. The method as recited in claim 13, wherein the step c) includes the steps of:
c1) forming a polysilicon layer, a barrier layer, a tungsten layer, a hard mask layer and an ARC layer on the gate oxide layer in sequence;
c2) patterning the ARC layer and the hard mask layer by using a photoresist mask formed on the ARC layer, thereby forming an ARC layer and a hard mask; and
c3) forming the tungsten polymetal gate electrode by patterning the tungsten layer, the barrier layer, the polysilicon layer and the gate oxide layer into a predetermined configuration using the ARC mask and the hard mask.

23. The method as recited in claim 13, wherein the selective oxide has the thickness in the range of about 1 Å to about 100 Å.
